(19) United States
(12) Patent Application Publication
(10) Pub. No.: US 2007/0054471 A1
(43) Pub. Date: Mar. 8, 2007

(54) ALIGNMENT MARK AND METHOD OF FORMING THE SAME

(76) Inventors: Chun-Fu Chen, Hsinchu (TW); Chi-Tung Huang, Hsinchu (TW); Yung-Tai Hung, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,034

(22) Filed: Aug. 26, 2005

(51) Int. Cl. H01L 21/00

(52) U.S. Cl. 438/462; 716/19; 716/21; 257/E23.179; 216/41

(57) ABSTRACT

An alignment mark is fabricated containing a mark portion and a trench structure. The trench structure surrounds the mark portion and is at a distance from the mark portion. The mark portion has a plurality of notches. Due to the erosion effect caused by the trench structure, it can prevent the residue leave in the notches of the alignment mark.

### BACKGROUND OF THE INVENTION

1. Field of Invention

The present invention is related to an alignment mark and its fabrication method. In particularly, it is related to an alignment mark having no residues and its fabrication method.

2. Description of Related Art

It is typically found in semiconductor fabrication process that the first procedure involves the fabrication of an alignment mark, and followed by the fabrication of a shallow trench isolation structure. However, during the fabrication of the shallow trench isolation structure, the alignment mark can be affected by the later described issues as shown in the drawings below.

FIG. 1A to FIG. 1C are cross-sectional views illustrating the alignment mask for a conventional method of making the shallow trench isolation structure.

Referring to FIG. 1A, after the alignment mark pattern 102 is formed on the substrate 100 in advance, the pad oxide layer 104 and the silicon nitride layer 106 are sequentially formed on the substrate 100 for use as the mask for shallow trench forming. A thick layer of oxide layer 108 is then deposited after forming the shallow trench. At this time, because of the contour of the alignment mark pattern 102, it leads to the surface indentation of silicon nitride layer 106 formed above the mark pattern 102.

Later, referring to FIG. 1B, another procedure used typically is the chemical mechanical polishing process (CMP) for removing the oxide layer 108 outside the shallow trench. However, STI CMP will be stopped when polishing to nitride layer 106; therefore, after the planarization process, it leaves ample residues of the oxide layer 108 behind inner the mark pattern 102.

Finally, referring to FIG. 1C, the conventional fabrication process of the shallow trench isolation structure uses hot phosphoric acid for removing the silicon nitride layer 106. But because the oxide layer 108 residue is not easily removed by the hot phosphoric acid; therefore, it leaves a silicon nitride layer 106 below the oxide layer 108. In addition, the residue typically (including the silicon nitride layer 106 and the oxide layer 108) appears at different locations; therefore, it can affect follow-up processes for alignment. Especially in regards to the shrinking dimensions for the semiconductor device, the issues of the residue with respect to the positional alignment between layers are more serious.

### SUMMARY OF THE INVENTION

An objective for the present invention is for providing an alignment mark, which does not possess any issues regarding residues.

Another objective for the present invention is for providing a fabrication method for the alignment mark to prevent the forming of residues.

The present invention proposes an alignment mark, including a mark portion having several notches and a trench structure surrounding the mark portion and at a distance from the mark portion.

According to the described alignment mark in an embodiment of the present invention, the aforementioned notches for the mark portion are aligned in different directions.

According to the described alignment mark in an embodiment of the present invention, the aforementioned trench structure includes a dielectric layer, and the dielectric layer includes high-density plasma oxide layer.

According to the described alignment mark in an embodiment of the present invention, the depth for the aforementioned trench structure is larger than that for each notch, and the width for the trench structure is larger than that for each notch.

According to the described alignment mark in an embodiment of the present invention, the aforementioned trench structure includes a shallow trench isolation structure (STI) or a deep trench.

According to the described alignment mark for an embodiment of the present invention, the in-between distance for the aforementioned trench structure and mark portion is about 15 m to 30 m.

The present invention further proposes a fabrication method for an alignment mark, including first a substrate is provided. And the substrate includes a mark area and a trench area, wherein the trench area surrounds the mark area and the mark area is kept at a distance. Thereafter, several notches are formed on the substrate surface within the mark area. A mask layer is then formed on the substrate filling the notches, and the substrate in the trench area is exposed. Thereafter, a portion of the exposed substrate is removed to form a trench by using the mask layer as the mask. Afterwards, a dielectric layer is formed on the substrate filling the aforementioned trench, and the dielectric layer is planarized to remove the dielectric layer outside the trench. Finally the mask layer is removed.

According to the aforementioned fabrication method for the alignment mask of an embodiment of the present invention, the aforementioned substrate further includes a shallow trench isolation area. Therefore, the procedure of forming the mask layer on the substrate includes exposing the substrate in the shallow trench isolation area. The procedure of removing a portion of the exposed substrate also includes forming a shallow trench. The procedure of forming a dielectric layer above the substrate also includes filling the shallow trench. In addition, the procedure of planarazing the dielectric layer also includes removing the dielectric layer outside the shallow trench for forming a shallow trench isolation structure.

According to the described fabrication method for the alignment mask for an embodiment of the present invention, the method for forming the dielectric layer above the aforementioned substrate includes a high-density plasma process.

According to the fabrication method for an embodiment of the present invention, the aforementioned method for planarazing the dielectric layer includes a chemical mechanical polishing process.

According to the fabrication method for the alignment mark for an embodiment of the present invention, the material for the aforementioned mask layer includes silicon nitride. Furthermore, the method for removing the mask layer can use hot phosphoric acid as the removing solvent.

Because the present invention establishes a trench structure surrounding the mark portion of the alignment mark; therefore, during the planarazing process by means of the erosion effect by the trench structure, residues on top of the notches for the mark portion are prevented, and thus guarantee the accuracy of alignment for the subsequent process.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further under-standing of the invention, and are incorporated in and constitute a part of this specification. The drawings illustrate embodiments of the invention and, together with the description, serve to explain the principles of the invention.

FIG. 1A to FIG. 1C are cross-sectional views illustrating the alignment mark used during the conventional fabrication of shallow trench isolation structure.

FIG. 2 is a top view illustrating the alignment mark according to a first embodiment for the present invention.

FIG. 3A to FIG. 3E are the fabrication process flow cross-sectional views illustrating the alignment mark for the second embodiment of the present invention.

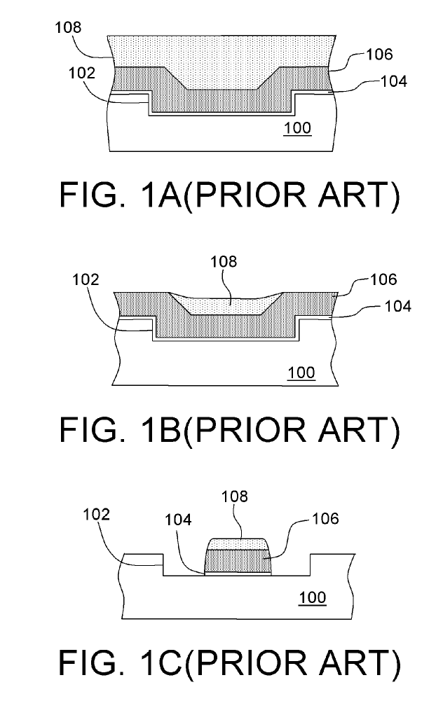

### DESCRIPTION OF THE PREFERRED EMBODIMENTS

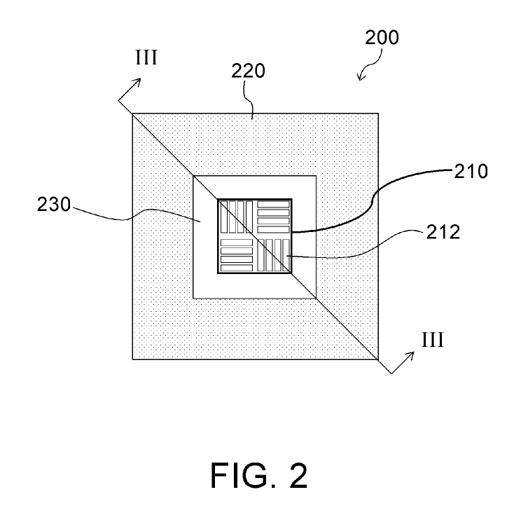

FIG. 2 is a top view illustrating an alignment mark 200 for a first embodiment for the present invention.

Referring to FIG. 2, the alignment mark 200 includes a mark portion 210. And the mark portion 210 has a plurality of notches 212. In addition, each notch 212 can be aligned in different directions. Furthermore, a trench structure 220 is surrounding the outside of the mark portion 210. And in between the trench structure 220 and the mark portion 210, lies a distance 230. In particularly, as the depth of the trench structure 220 becomes larger than that for each notch 212, the width for the trench structure 220 also becomes larger than that for each notch 212. The residue on the notch 212 can be removed by erosion effect caused by the trench structure 220 during processing period. The depth of the notch 212 is, for example, between 1200 angstroms to 1400 angstroms. Or it can vary according to the device dimensional changes. Furthermore, the aforementioned trench structure 220, for example, includes a dielectric layer, and the dielectric layer includes a high-density plasma oxide layer. In addition, the trench structure 220 in the present embodiment can be a shallow trench isolation structure (STI) or a deep trench. And the distance between the trench structure 220 and the mark portion 210 is about 15 m to 30 m.

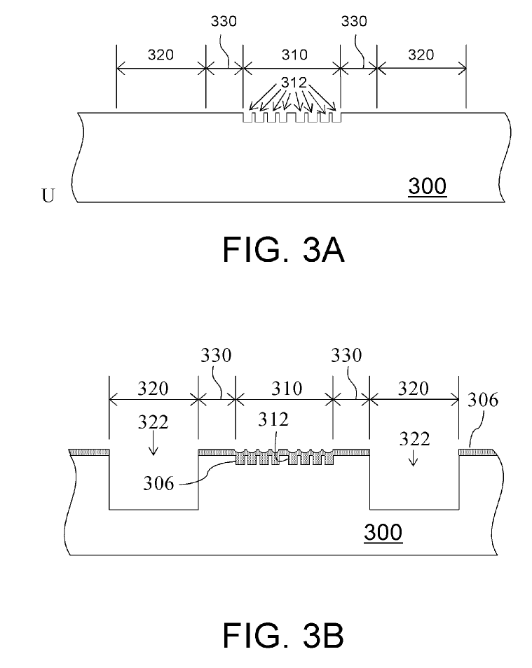

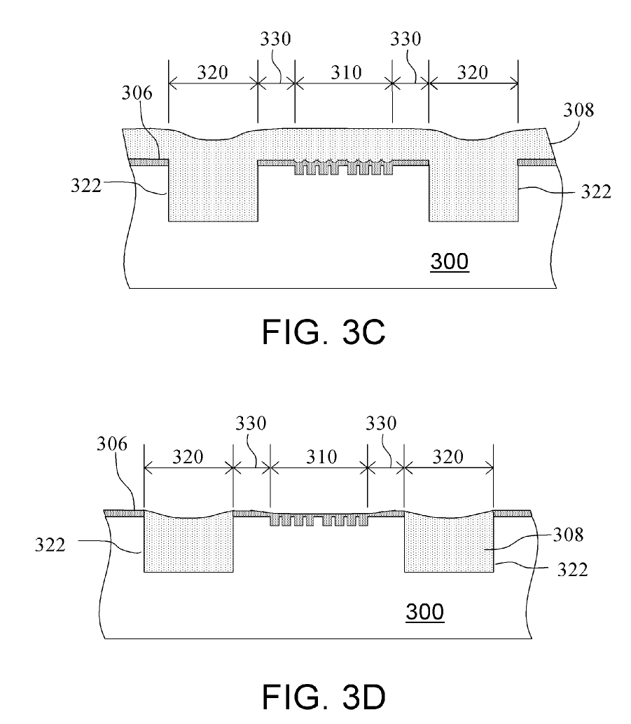

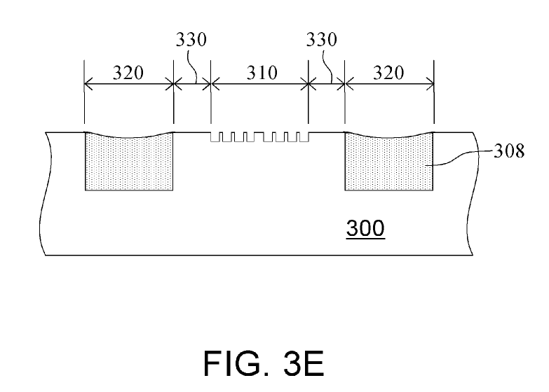

FIG. 3A to FIG. 3E are cross-sectional views illustrating the fabrication process for the alignment mark in a second embodiment of the present invention. And they can also be cross referenced to the line III-III′ of FIG. 2.

Referring to FIG. 3A, first a substrate 300 is provided. And the substrate 300 has a mark area 310 and a trench area 320 in advance, in which the trench area 320 surrounds the mark area 310 and maintains a distance 330 between with the mark area 310. Later, a plurality of notches 312 is formed on the surface of the substrate 300 in the mark area 310. Afterwards, a pad layer (not illustrated) can be formed on the substrate 300 surface. Furthermore, the aforementioned substrate 300 can further include a shallow trench isolation area (not illustrated) for forming shallow trench isolation structure (STI). Because the fabrication process for the shallow trench isolation structure can be done using the conventional technology as reference; therefore, the fabrication process for forming the shallow trench isolation structure can be referred to the fabrication procedure of trench in the trench area 320.

Afterwards, referring to FIG. 3B, a mask layer 306 is formed above the substrate 300 filling the notch 312, and the substrate 300 in the trench area 320 is exposed. At this time, because of the contour of the notches 312, it leads to the forming of uneven surface for the mask layer 306 on the notches 312. Later, a portion of the exposed substrate 300 is removing to form a trench 322 by using the mask layer 306 as a mask. Of course, if the other portions of the substrate 300 contain a shallow trench isolation area, the substrate 300 in the shallow trench isolation area is concurrently exposed during the forming of the mask layer 306. During the removal of a portion of the exposed substrate 300, the shallow trench is also formed at the same time.

Later, referring to FIG. 3C, a dielectric layer 308 is formed on the substrate 300 filling the aforementioned trench 322, and at the same time covering the mask layer 306. In addition, the method for forming the dielectric layer 308 includes a high-density plasma process. At this time if the substrate 300 still contains the shallow trench isolation area, the aforementioned shallow trench will also be filled by the dielectric layer 308.

Afterwards, referring to FIG. 3D, the dielectric layer 308 is planarizied to remove the dielectric layer 308 outside the trench 322. In addition, the method of planarazing dielectric layer 308 such as chemical mech-anical polishing process (CMP) is used. Because of the erosion effect during the planarazing process caused by the trench 322, as a result, the mask layer 306 in the mark area 310 is completely eroded, thus the dielectric layer 308 in the mark area 310 can be completely removed, and no residue is left. If the substrate 300 has a shallow trench isolation area, the shallow trench isolation structure (not illustrated) can be formed by removing the dielectric layer 308 outside the shallow trench.

Finally, referring to FIG. 3E, the mask layer 306 is removed. When the aforementioned mask layer 306 material is, for example, silicon nitride, the hot phosphoric acid can be used as the solvent for removing the mask layer 306.

Based on the above mentioned, because of the trench structure is disposed surrounding the mark portion of the alignment mark in the present invention, residues on the mask layer above the notch of the mark portion are prevented during the planarazing process because of the erosion effect caused by the trench structure. During the subsequent removal of the mask layer, the mask layer can be completely removed from the notches for the alignment mark.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. An alignment mark, comprising:
a mark portion, having a plurality of notches; and
a trench structure, surrounding the mark portion and disposed at a distance to the mark portion, wherein the distance between the trench structure and the mark portion is between 15 um to 30 um.

2. The alignment mark according to claim 1, wherein the notches for the mark portion are aligned in a plurality of directions.

3. The alignment mark according to claim 1, wherein the trench structure comprises a dielectric layer.

4. The alignment mark according to claim 3, wherein the dielectric layer comprises a high-density plasma oxide layer.

5. The alignment mark according to claim 1, wherein the depth for the trench structure is larger than that for each notch.

6. The alignment mark according to claim 1, wherein the width for the trench structure is larger than that for each notch.

7. The alignment mark according to claim 1, wherein the trench structure is comprised of a shallow trench isolation structure or a deep trench.

8-18. (canceled)

19. The alignment mark according to claim 1, wherein the thickness at the center portion of the trench structure is lower than that of the edge portion of the trench structure.
